(19) United States
(12) Patent Application Publication
(10) Pub. No.: US 2021/0308509 A1
(43) Pub. Date: Oct. 7, 2021

(54) EXPLOSION-PROOF ARRANGEMENT

(71) Applicant: R. STAHL SCHALTGERÄTE GMBH, Waldenburg (DE)

(72) Inventors: Clife HERMANOWSKI, Seckach (DE); Thorsten ARNHOLD, Pfedelbach (DE)

(21) Appl. No.: 17/268,259

(22) PCT Filed: Aug. 7, 2019
(86) PCT No.: PCT/EP2019/071254

§ 371 Date: Feb. 12, 2021

(30) Foreign Application Priority Data
Aug. 16, 2018 (DE) 10 2018 119 947.3

(51) Int. Cl. A62C 4/00; F25D 23/06; H05K 7/20

(52) U.S. Cl. CPC A62C 4/00; F25D 23/061; H05K 7/20354; H05K 7/20318; H05K 7/20309

(57) ABSTRACT

The invention relates to an explosion-proof arrangement (10) having an explosion-proof housing (11) which encloses a housing interior (13) and which is designed with the pressure-resistant encapsulation type of flame-proof protection. The housing interior (13) is subdivided into a first subregion (16) and a second subregion (17) by an intermediate wall (15) in such a way that the two subregions (16, 17) are explosion-proof relative to one another and consequently each subregion (16, 17) provides the pressure-resistant encapsulation type of flame-proof protection. At least one outer wall section (12a) of an outer wall (12) of the housing (11) is designed in a flame-proof and gas-permeable manner and allows gas exchange between the second subregion (17) and the surrounding area (14). A refrigeration machine (22) is arranged in the housing interior (13), wherein the evaporator (27) is located in the first subregion (16) and the condenser (24) is located in the second subregion (17). Heat from at least one electrical and/or electronic device (21) or another heat source in the first subregion (16) can therefore be dissipated into the second subregion (17) and from there to the surrounding area (14). This measure can prevent hotspots, which can ignite the explosion-hazard atmosphere in the surrounding area (14), from forming locally.

### CROSS REFERENCE TO RELATED APPLICATIONS

This application is a National Stage of PCT Application No. PCT/EP2019/071254 filed on Aug. 7, 2019, which claims priority to German Patent Application No. 10 2018 119 947.3 filed on Aug. 16, 2018, the contents each of which are incorporated herein by reference thereto.

### BACKGROUND

The invention refers to an explosion-proof arrangement comprising an explosion-proof housing as well as a chiller for cooling of a housing interior.

DE 32 03 799 A1 discloses an explosion-proof refrigerator. There the explosive components are installed in a gas tight housing such that they are unable to ignite the explosive atmosphere outside the housing. The evaporator of the refrigerator is located in the interior of the refrigerator that is to be cooled, whereas the condenser is arranged outside of the cooling chamber.

Explosion-proof housings are configured to enclose ignition sources and to avoid the ignition of an explosive atmosphere in the environment of the housing. Ignition sources can be, for example, devices with electrical and/or electronic components. When such devices are housed in the housing it has to be ensured that the heat created during operation of the device is dissipated from the housing interior. Also the whole arrangement must not have temperatures at any location that could lead to an ignition of the explosive atmosphere.

### BRIEF SUMMARY

Thus, it can be considered as object of the present invention to provide an explosion-proof arrangement that guarantees high safety with simple configuration.

Disclosed is an explosion-proof arrangement, including: an explosion-proof housing, wherein the housing encloses a housing interior that is subdivided into a first compartment and a second compartment by an intermediate wall, wherein the intermediate wall forms a flameproof barrier between the first compartment and the second compartment and wherein at least one gas-permeable outer wall section of the housing adjoining the second compartment is configured to allow a flameproof gas exchange with an explosive atmosphere in an environment of the housing; at least one device forming a potential ignition source that is arranged in the first compartment that radiates heat during operation in the first compartment; and a chiller comprising an evaporator arranged in the first compartment and a condenser arranged in the second compartment.

The inventive explosion-proof arrangement comprises an explosion-proof housing that is realized in the ignition protection category flameproof enclosure (Ex−d). The housing has multiple housing outer walls that enclose a housing interior. Relative to an environment the housing interior is enclosed by the outer walls of the housing for forming of the flameproof enclosure.

In addition, the explosion-proof housing has an intermediate wall in the housing interior that divides the housing interior in a first compartment and a second compartment. A gas exchange is possible between the second compartment and the environment. At least one outer wall section adjoining the second compartment is configured in a gas-permeable manner and is configured to allow a flameproof gas exchange with the explosive atmosphere in the environment. For this the gas-permeable outer wall section itself can be made of a gas-permeable flameproof material or it can comprise a gas-permeable flameproof configured passage.

The explosion-proof housing is not necessarily one single housing. The two compartments can be formed by originally separate housing parts that are joined together. For example, a housing part having the second compartment can be flanged to a housing part having the first compartment.

The explosion-proof arrangement comprises in addition at least one electrical and/or electronic device that is arranged in the first compartment. During operation the device radiates heat in the first compartment. For dissipating the heat from the first compartment, the explosion-proof arrangement comprises a chiller. The chiller has an evaporator arranged in the first compartment and a condenser arranged in the second compartment.

The intermediate wall forms a flameproof barrier between the two compartments. Both compartments are respectively configured individually in the ignition protection category flameproof enclosure (Ex−d). This means that an ignition inside the first compartment does not result in an ignition or explosion in the second compartment and vice versa. It is also achieved that the volumes of the two compartments are smaller than the total housing interior and thus the explosion pressure that the housing has to withstand can be reduced compared with the housing having one single continuous housing interior of the same size.

By arranging the evaporator in the second compartment, it is ensured that the heat created by the chiller at the evaporator does not result in an ignition of the explosive atmosphere. By means of the chiller it can be ensured that the heat created from one or more heat sources in the first compartment can be absorbed and at least partly transferred in the second compartment. By arranging the flow channels of the chiller in the first compartment, not only the gas temperature in the interior of the first compartment can be influenced, but hot spots on the outer walls of the housing surrounding the first compartment can be selectively avoided. Specifically the temperature on the outer walls must not exceed a pre-defined temperature threshold on any location in order to avoid an ignition of the surrounding explosive atmosphere by a hot housing location.

The heat transferred in the second compartment can be dissipated to the environment by gas exchange. Concurrently it is avoided that potentially present high temperatures at the condenser in the second compartment can result in an ignition of the surrounding atmosphere, because also the second compartment is enclosed in a flameproof manner relative to the environment.

It is advantageous, if the housing comprises outer wall sections adjoining the first compartment that seal the first compartment relative to the environment substantially in a gas tight manner.

At least one door, at least one flap or at least one cover of the housing can provide access to the first compartment and/or second compartment such that between the first compartment and the environment flameproof gaps can be present. Through such flameproof gaps no substantial and particularly no intentional gas exchange occurs. The at least one door, the at least one flap or the at least one cover can close in a gas tight manner. The expression “gas tight” means here a configuration that does not allow any gas exchange or at least does not allow a specifically initiated intentional gas exchange between the housing interior and the environment.

In addition, it is advantageous, if the intermediate wall of the housing seals the first compartment relative to the second compartment in a gas tight manner. Thus, no specifically initiated gas exchange occurs between the two compartments.

In an alternative embodiment the intermediate wall of the housing of the explosion-proof arrangement is configured such that a flameproof gas exchange is allowed between the two compartments. Thereby the intermediate wall can be configured in the same manner as the gas-permeable outer wall section of an outer wall of the housing adjoining the second compartment.

For example, for creation of the gas permeability parts of the respective wall or the whole wall can be made of a porous material and/or a mesh containing grid-like material. Due to such a configuration, a gas exchange is possible on one hand and the escape of flames, sparks, hot gases or the like is avoided on the other hand.

For example, a gas-permeable flameproof wall section can be made of a structure of entangled fibers. In another embodiment one or more grid layers can be arranged on top of each other. The gas-permeable flameproof wall section has an average mesh or pore size in the range of about 80 μm to 250 μm. The thickness of the gas-permeable flameproof wall section has an amount of at least 5 mm or at least 10 mm. Preferably the flameproof gas-permeable wall section is made from a material having a temperature resistance of at least 400° C. For example, the gas-permeable flameproof wall section can be made of a chromium steel alloy, such as stainless steel.

In addition, it is advantageous that the chiller comprises a compressor that is arranged in the first compartment. The chiller also has an expansion device that is preferably arranged in the first compartment. Further at least on fan can be arranged in the first compartment and/or the second compartment in order to effectuate an air circulation. Arranging a fan in the first compartment is particularly advantageous, if the intermediate wall allows a flameproof gas exchange between the two compartments.

A protection cover can be arranged on the outside of the housing that is configured to cover the flameproof gas-permeable outer wall section adjoining the second compartment, particularly in order to avoid intrusion of splash water through the gas-permeable outer wall section in the second compartment. Thereby it can be advantageous, if the protection cover comprises at least one opening in order to allow the gas exchange between the second compartment and the environment. The at least one opening is preferably not arranged in direct straight line opposite the gas-permeable outer wall section, particularly in order to achieve the desired splash water protection.

Preferably the inner volume of the first compartment is larger than the inner volume of the second compartment.

In an embodiment the explosion-proof arrangement comprises a control device for control of the chiller. The control device is configured to control or feedback control the temperature in the first compartment and/or in the second compartment in cooperation with the chiller. Additionally or alternatively, the control device can also control the at least one fan that can be arranged in the first compartment and/or the second compartment. In doing so, it is advantageous, if at least in the first compartment at least one temperature sensor is provided in order to determine the temperature in the respective compartment and/or on an outer wall area of the housing that encloses the respective compartment.

### BRIEF DESCRIPTION OF THE DRAWINGS

Advantageous embodiments of the invention are derived from the dependent claims, the description and the drawings. In the following preferred embodiments of the invention are explained in detail with reference to the attached drawings. The drawings show:

FIG. 1 a schematic block-diagram-like illustration of an embodiment of an explosion-proof arrangement comprising an explosion-proof housing as well as a chiller,

FIGS. 2 and 3 a modified embodiment of the explosion-proof arrangement of FIG. 1 respectively and

FIGS. 4 and 5 a schematic perspective illustration of a gas-permeable flameproof structure respectively, as it can be used for a wall or a wall section in any embodiment of the explosion-proof arrangement.

### DETAILED DESCRIPTION

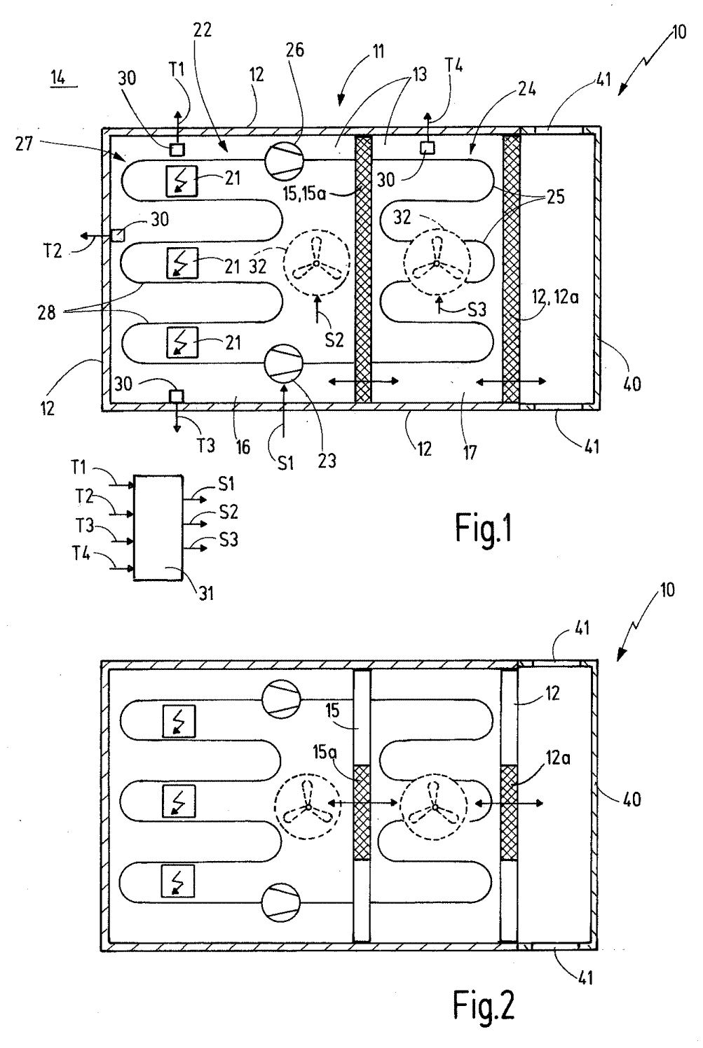

FIG. 1 schematically shows an embodiment of an explosion-proof arrangement 10 that comprises an explosion-proof housing 11. The explosion-proof housing 11 has multiple and preferably six outer walls 12, of which only four outer walls are illustrated in the schematic sectional view in FIG. 1. For example, the housing 11 as a whole as a cuboid-shaped form. The housing 11 can also have other forms, such as cylindrical, prismatical or other free forms with planar and/or curved outer walls 12. The outer walls 12 enclose a housing interior 13 and separate it in a flameproof manner from an environment 14 having an explosive atmosphere surrounding the housing 11. The housing 11 is configured in the ignition protection category flameproof enclosure (Ex−d) according to one of the standards EN60079-1 or IEC 60079-1.

The housing interior 13 is separated by means of an intermediate wall 15 of the housing 11 in a first compartment 16 and a second compartment 17. The intermediate wall 15 is configured such that it separates the first compartment in a flameproof manner from the second compartment 17. The intermediate wall thus forms a flameproof barrier between the two compartments 16, 17. Both compartments 16, 17 are individually respectively configured in an explosion-proof manner in the ignition protection category flameproof enclosure (Ex−d).

A device that can be an ignition source for the explosive atmosphere in the environment 14, e.g. at least one electrical and/or electronic device 21 that is arranged in the first compartment 16 of the housing 11 or the housing interior 13 is part of the explosion-proof arrangement 10. The at least one electrical and/or electronic device 21 is housed in the first compartment 16 of the housing 11 in an explosion-proof manner. Potential electrical connections or conductors from the environment 14 into the first compartment 16 are guided through an outer wall 12 in an explosion-proof manner as known in the field of explosion protection per se. Such conductors or connections can be guided through the outer wall 12 in the first compartment 16 in an explosion-proof manner by forming a flameproof gap or by casting in a gas tight manner with the outer wall 12 or in another explosion-proof manner.

During operation the at least one electrical and/or electronic device 21 creates heat. The heat is radiated in the first compartment 16 and heats the outer walls 12 enclosing the first compartment 16. In addition, during operation of the at least one device 21 the temperature in the atmosphere of the first compartment 16 is increased, which can also be undesired for the operation of the at least one electrical and/or electronic device 21. For effectively dissipating heat out of the first compartment 16 the explosion-proof arrangement 10 comprises a chiller 22. The chiller 22 provides a closed fluid circuit of a cooling medium that takes different aggregate conditions in the fluid circuit. The cooling medium is compressed by means of a compressor 23 of the chiller 22 and is condensed and thus liquefied in a heat exchanger or condenser 24 following the compressor 23. During liquefaction of the cooling medium heat is radiated. The condenser 24 is arranged in the second compartment 17.

In the embodiment the condenser 24 is formed by a condenser tube coil 25 that is arranged in serpentine or meandering manner in the second compartment 17. The condenser tube coil 25 is guided through the intermediate wall 15 in a flameproof manner and is fluidically connected at one end with the compressor 23, whereas the other opposite end is fluidically connected with an expansion device 26 of the chiller 22.

The expansion device 26 can, for example, comprise an expansion valve and/or capillary tube. The expansion device 26 reduces the pressure of the cooling medium and the cooling medium is downstream of the expansion device 26 channeled to a heat exchanger or evaporator 27. In the evaporator 27 the cooling medium absorbs heat and evaporates at relatively low temperature. This process is also called evaporative cooling. Then the cooling medium from the evaporator 27 is again supplied to the compressor 23 and in doing so, a closed fluid circuit of the chiller 22 is achieved.

The evaporator 27 is arranged in the first compartment 16 in order to absorb heat that is radiated there from the at least one electrical and/or electronic device 21. In the embodiment also the compressor 23 and the expansion device 26 are arranged in the first compartment 16. In doing so, standard components or units can be used for the chiller. All of the components of the chiller 22 are arranged in an explosion-proof manner either in the first compartment 16 or in the second compartment 17.

Analog to the condenser 25 the evaporator 27 is formed by a serpentine-shaped or meander-shaped evaporator tube coil that can be placed in the first compartment 16 such that the heat radiation of the at least one electrical and/or electronic device 21 and the absorption by the cooling medium is optimized, particularly in that a section of the evaporator tube coil 28 is in spatial proximity to the at least one electrical and/or electronic device 21. In addition or as an alternative, at least sections of the at least one evaporator tube coil 28 can be placed along one or multiple outer walls 12—or at least sections thereof—that adjoin the first compartment 16. In doing so, a too high local heating of a respective outer wall 12 can be avoided.

For measurement of at least one temperature, at least one temperature sensor 30 can be arranged in the first compartment 16 and/or second compartment 17 that respectively creates a corresponding temperature signal T1 to T4 and is configured to transmit the respective temperature signal T1 to T4 to a control device 31. In the embodiment three temperature sensors 30 are arranged in the first compartment 16 that create a first temperature signal T1, a second temperature signal T2 and a third temperature signal T3 and transmit them to the control device 31. According to the example, an additional temperature sensor 30 is arranged in the second compartment 17 that creates a fourth temperature signal T4 and transmits it to the control device 31. The control device 31 can evaluate the temperature signals T1 to T4 and control the chiller 22, e.g. the compressor 23, by a first control signal S1.

In the embodiment illustrated in FIG. 1 it is shown in dashed lines that at least one fan can be arranged in the first compartment 16 and/or the second compartment 17 respectively in order to create an air circulation. For each provided fan 32 the control device 31 can create a respective control signal, e.g. a second control signal S2 for a fan 32 in the first compartment 16 and a third control signal S3 for a fan 32 arranged in the second compartment 17.

As schematically illustrated in FIGS. 1-3, at least an outer wall section of an outer wall 12 adjoining the second compartment 17 is configured as gas-permeable outer wall section 12a. In the embodiment illustrated in FIG. 1, one of the outer walls 12 adjoining the second compartment 17 is completely configured as gas-permeable outer wall, such that the gas-permeable outer wall section 12a forms the whole outer wall 12. The gas-permeable outer wall section 12a is configured in a flameproof manner, such that the second compartment 17 is explosion-proof with regard to the environment 14 and according to the example, complies with the requirements of a flameproof enclosure (Ex−d).

FIGS. 4 and 5 show highly schematically material structures respectively that fulfill provision of a flameproof gas exchange. For example, the gas-permeable outer wall section 12a can be formed by porous material 35 that is manufactured, for example, from a structure material of entangled fibers. The porous material 35 thereby comprises fibers entangled with one another, disorderly arranged that can have a diameter of about 70 μm to 130 μm. The pore size of the porous material 35 can have an amount of at least 80 μm and at most 250 μm. The porosity of the porous material 35 is preferably in a range of 60% to 80%.

In addition or as an alternative, the gas-permeable outer wall section 12a can be formed of a mesh or grid material 36 (FIG. 5). The mesh size has an amount of about at least 80 μm and at most 250 μm. Multiple layers 37 having different grid structures or grid bar orientations can be arranged on top of each other in order to allow a gas flow through the grid material 36 on one hand and to extinguish flames, sparks and hot gases on the other hand.

Also a combination of porous material 35 with grid material 36 is possible in order to form a gas-permeable outer wall section 12a.

A gas exchange between the second compartment 17 and the environment 14 is possible through the at least one gas-permeable outer wall section 12a. In doing so, heat radiated from the condenser 24 in the second compartment 17 can be dissipated outward in the environment 14. As already explained, for this a fan 32 can be arranged in the second compartment 17 in order to improve the gas exchange between the second compartment 17 and the environment 14.

As illustrated in FIGS. 1 and 2, the intermediate wall 15 can also comprise at least one gas-permeable intermediate wall section 15a that is configured in a flameproof manner. The flameproof gas-permeable intermediate wall section 15a can be configured analog to the gas-permeable outer wall section 12a and for this can comprise, for example, porous material 35 and/or grid material 36, which allows a gas exchange between the first compartment 16 and the second compartment 17 on one hand and however maintains the flameproof condition between the first compartment 16 and the second compartment 17 on the other hand.

In the embodiment illustrated in FIG. 1, the intermediate wall 15 is completely configured in a flameproof and gas-permeable manner analog to an outer wall 12 adjoining the second compartment 17. In modification thereto the intermediate wall 15 and/or an outer wall 12 can also be partly gas-permeable and can comprise an insert, for example, in order to form the gas-permeable outer wall section 12a and/or the gas-permeable intermediate wall section 15a, as schematically illustrated in FIG. 2.

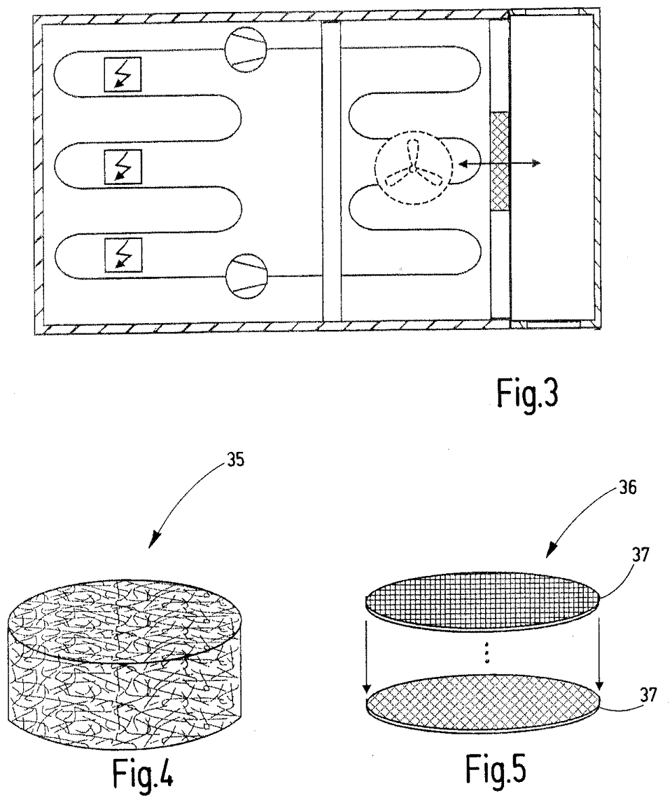

In another alternative embodiment the intermediate wall 15 can also be substantially gas-impermeable, such that no purposed and intentional gas exchange occurs between the two compartments 16, 17 (FIG. 3).

The embodiments according to FIGS. 1-3 can also be combined with each other. For example, in all embodiments a complete outer wall adjoining the second compartment 17 can be realized in a flameproof and gas-permeable manner, as shown in FIG. 1. In the embodiment shown in FIG. 3 the intermediate wall 15 can be realized according to the embodiment of FIG. 1. Apart therefrom the embodiments according to FIGS. 1-3 are identical, such that reference can be made to the description of FIG. 1 above. For sake of clarity, the temperature sensors 30 and the control device 31 have been omitted in FIGS. 2 and 3.

In the embodiment shown in FIG. 3 having a substantially gas-impermeable intermediate wall 15 no fan 32 is provided in the first compartment 16 according to the example. In this embodiment at least one fan 32 can be sufficient in the second compartment 17 in order to support the air circulation between the second compartment 17 and the environment 14. Depending on the configuration of the chiller 22 and particularly the evaporator 27, in the embodiment according to FIG. 3 also a fan 32 can be provided in the first compartment 16, if an air circulation within the first compartment 16 is advantageous to support the heat transfer to the evaporator 27 and/or an improved temperature distribution in the first compartment 16 and the outer walls 12 of the housing 11 adjoining the first compartment 16.

As an option, the explosion-proof arrangement 10 can in addition comprise a protection cover 40 that is configured to cover the at least one flameproof gas-permeable outer wall section 12a and is arranged on the outside of housing 11. The protection cover 40 covers the at least one gas-permeable outer wall section 12a, particularly in order to protect it from splash water that is directly directed at the gas-permeable outer wall section 12a. The protection cover 40 comprises at least one and preferably multiple openings 41 in order to allow the gas exchange between the second compartment 17 and the environment 14. The at least one opening 41 is arranged such that it is not opposed to the gas-permeable outer wall section 12a in straight direction.

An effective heat transfer of the heat radiated by the at least one electrical and/or electronic device 21 out of the first compartment 16 in the second compartment 17 is provided by the explosion-proof arrangement 10. In the second compartment 17 an air circulation with the environment is allowed in order to emit warm air to the outside and to receive cooler air from the environment 14. All in all, a very uniform heat distribution is achieved. In doing so, hotter locations on the outer walls 12 of housing 11 are avoided that could serve as ignition sources for the explosive atmosphere in the environment 14. For control or feedback control of the chiller 22 the temperature can be determined at one or more locations, particularly also at least one temperature of the housing wall 12 of housing 11, particularly at a location at which the danger exists that the respective outer wall 12 of housing 11 is remarkably heated and could serve as ignition source.

The invention refers to an explosion-proof arrangement 10 comprising an explosion-proof housing 11 that encloses a housing interior 13 and that is configured in the ignition protection category flameproof enclosure. The housing interior 13 is divided in a first compartment 16 and a second compartment 17 by means of an intermediate wall 15 such that the two compartments 16, 17 are explosion-proof relative to each other and thus each compartment 16, 17 complies with the ignition protection category flameproof enclosure. At least one outer wall section 12a of an outer wall 12 of housing 11 is configured in a flameproof and gas-permeable manner and allows a gas exchange between the second compartment 17 and the environment 14. In the housing interior 13 a chiller 22 is arranged, wherein the evaporator 27 is located in the first compartment 16 and the condenser 24 is located in the second compartment 17. Heat of at least one electrical and/or electronic device 21 or another heat source in the first compartment 16 can thus be dissipated in the second compartment 17 and from there in the environment 14. Due to this measure, it can be effectively avoided that locally hot spots are created that could ignite the explosive atmosphere in the environment 14.

### LIST OF REFERENCE SIGNS

10 explosion-proof arrangement
11 housing
12 outer wall
12a gas-permeable outer wall section
13 housing interior
14 environment
15 intermediate wall
15a gas-permeable intermediate wall section
16 first compartment
17 second compartment
21 electrical and/or electronic device
22 chiller
23 compressor
24 condenser
25 condenser tube coil
26 expansion device
27 evaporator
28 evaporator tube coil
30 temperature sensor
31 control device
32 fan
35 porous material
36 grid material
37 layer
40 protection cover
41 opening
S1 first control signal
S2 second control signal
S3 third control signal
T1 first temperature signal
T2 second temperature signal
T3 third temperature signal
T4 fourth temperature signal

1. An explosion-proof arrangement, comprising:
an explosion-proof housing, wherein the housing encloses a housing interior that is subdivided into a first compartment and a second compartment by an intermediate wall, wherein the intermediate wall forms a flameproof barrier between the first compartment and the second compartment and wherein at least one gas-permeable outer wall section of the housing adjoining the second compartment is configured to allow a flameproof gas exchange with an explosive atmosphere in an environment of the housing;
at least one device forming a potential ignition source that is arranged in the first compartment that radiates heat during operation in the first compartment; and
a chiller comprising an evaporator arranged in the first compartment and a condenser arranged in the second compartment.

2. The explosion-proof arrangement according to claim 1, wherein the housing comprises outer wall sections adjoining the first compartment that enclose the first compartment in a gas-tight manner with respect to the environment.

3. The explosion-proof arrangement according to claim 1, wherein the intermediate wall of the housing closes the first compartment in a gas-tight manner relative to the second compartment.

4. The explosion-proof arrangement according to claim 1, wherein the intermediate wall of housing is configured to allow a flameproof gas exchange between the two compartment.

5. The explosion-proof arrangement according to claim 1, wherein the chiller comprises a compressor that is arranged in the first compartment.

6. The explosion-proof arrangement according to claim 1, wherein the chiller comprises an expansion device that is arranged in the first compartment.

7. The Explosion-proof arrangement according to claim 1, wherein at least one fan is arranged in the first compartment and/or the second compartment.

8. The explosion-proof arrangement according to claim 1, wherein the gas-permeable outer wall section of housing adjoining the second compartment is covered by a protection cover arranged on an outside of housing.

9. The explosion-proof arrangement according to claim 8, wherein the protection cover comprises at least one opening, wherein the at least one opening is not arranged directly opposite the gas-permeable outer wall section in a straight direction.

10. The explosion-proof arrangement according to claim 1, wherein and inner volume of the first compartment is larger than an inner volume of the second compartment.

11. The explosion-proof arrangement according to claim 1, wherein a control device for control of the chiller is provided in order to control or feedback control a temperature in the first compartment and/or the second compartment.

12. The explosion-proof arrangement according to claim 11, wherein the intermediate wall of the housing closes the first compartment in a gas-tight manner relative to the second compartment.

13. The explosion-proof arrangement according to claim 12, wherein the intermediate wall of housing is configured to allow a flameproof gas exchange between the two compartments.

14. The explosion-proof arrangement according to claim 13, wherein the chiller comprises a compressor that is arranged in the first compartment.

15. The explosion-proof arrangement according to claim 14, wherein the chiller comprises an expansion device that is arranged in the first compartment.

16. The Explosion-proof arrangement according to claim 15, wherein at least one fan is arranged in the first compartment and/or the second compartment.

17. The explosion-proof arrangement according to claim 16, wherein the gas-permeable outer wall section of housing adjoining the second compartment is covered by a protection cover arranged on an outside of housing.

18. The explosion-proof arrangement according to claim 17, wherein the protection cover comprises at least one opening, wherein the at least one opening is not arranged directly opposite the gas-permeable outer wall section in a straight direction.

19. The explosion-proof arrangement according to claim 18, wherein and inner volume of the first compartment is larger than an inner volume of the second compartment.

20. The explosion-proof arrangement according to claim 19, wherein a control device for control of the chiller is provided in order to control or feedback control a temperature in the first compartment and/or the second compartment.
